(19) United States
(12) Patent Application Publication
(10) Pub. No.: US 2008/0121901 A1
(43) Pub. Date: May 29, 2008

(54) LIGHT EMITTING DEVICE

(76) Inventors: Haksu Kim, Gumi-city (KR); Jaedo Lee, Gumi-city (KR); Hyodae Bae, Gumi-city (KR)

Correspondence Address: KED & ASSOCIATES, LLP, P.O. Box 221200, Chantilly, VA, 20153-1200, US

(21) Appl. No.: 11/944,489

(22) Filed: Nov. 23, 2007

(30) Foreign Application Priority Data
Nov. 23, 2006 (KR) 10-2006-0116618
Nov. 29, 2006 (KR) 10-2006-0119395
Dec. 29, 2006 (KR) 10-2006-0138248

(51) Int. Cl. H01L 33/00

(52) U.S. Cl. 257/88; 257/E33.062

(57) ABSTRACT

A light emitting device is disclosed. A light emitting device according to an embodiment of the present invention may include a substrate comprising a light emitting region and a non-light emitting region, a second electrode disposed over the substrate, a sub-pixel disposed in the light emitting region and comprising a light emitting layer disposed between a first electrode and the second electrode, a dummy area disposed in the non-light emitting region and comprising a dummy pad, an insulating film disposed over the substrate and covering half or more of the dummy pad, and common films disposed over the dummy pad or the insulating film. The dummy pad and the second electrode disposed corresponding to the dummy pad are spaced apart from each other.

This application claims the benefit of Korean Patent Application Nos. 10-2006-0116618 filed in Korea on Nov. 23, 2006, 10-2006-0119395 filed in Korea on Nov. 29, 2006 and 10-2006-0138248 filed in Korea on Dec. 29, 2006 which are hereby incorporated by reference.

### BACKGROUND OF THE DISCLOSURE

1. Field of the Disclosure

The present invention relates to displays, and more particularly, to a light emitting device.

2. Description of the Background Art

In general, with the development of information communication technologies, the demand for electronic displays is increased and required displays are also diversified in accordance with the needs of diversified information society.

In order to meet the needs of the diversified information society, it is required that electronic display devices have characteristics such as high definition, a large size, a low price, high performance, a thin type, and miniaturization. To this end, new Flat Panel Display (FPD) devices have been developed instead of the existing Cathode Ray Tube (CRT).

In particular, to develop materials for semiconductors and displays, and so on, which are concerned with communications and computers, is one of the major keys to the technology advancement of each industry field. Of several display devices that are being used, one display that has been in the spotlight in terms of an application to natural color display devices is a light emitting device.

The light emitting device has a rapid response speed when compared with light-receiving type devices such as liquid crystal display devices, and an excellent luminance because of a self-light emitting type. Further, the light emitting device is advantageous in that it is simple in structure, enabling easy fabrication, and has a light-weight and thin type.

FIGS. 1 to 3 are views illustrating a general light emitting device.

Referring to FIGS. 1 and 2, a dummy area X including a dummy pad 170 and a contact area Y including a contact pad 180 are disposed in a non-light emitting region NA. An insulating film 160 having opening formed therein is disposed on the dummy pad 170. Common films 145 may be disposed on the dummy pad 170 having opening formed therein in order to prevent a contact with a second electrode 150.

Referring to a region A, when depositing the common films 145 on the dummy pad 170, the common films 145 may be deposited very thinly or the dummy pad 170 may be partially exposed due to error in the deposition process. This makes the dummy pad 170 very close to or connect to the second electrode 150. Consequently, the leakage current is increased and therefore problems, such as defective spots (ex: dark spot), may occur.

Referring to FIG. 3, the insulating film 160 having the opening formed therein is also disposed on the contact pad 180. Second electrodes 150 and 151 are disposed over the contact pad 180 having opening formed therein, so the second electrodes 150 and 151 are electrically connected to the contact pad 180.

The second electrodes 150 and 151 may have a multi-layer structure. At this time, resistance can be increased at the contact interface of the second electrode 150 which is first formed, and the second electrode 151 which is then formed, or an oxide film 161 is formed between the second electrodes 150 and 151, insulating the second electrodes 150 and 151. Accordingly, a problem arises because the signal flow is hindered.

The above problems may cause defective spots in sub-pixels or hinder the signal flow. Consequently, the display quality of the light emitting device may be degraded.

### SUMMARY OF THE DISCLOSURE

Various embodiments of the present invention are advantageous in that they can improve the display quality by preventing defective spots due to the leakage current and a signal distortion phenomenon which may be generated in light emitting devices.

A light emitting device according to an embodiment of the present invention may include a substrate comprising a light emitting region and a non-light emitting region, a second electrode disposed over the substrate, a sub-pixel disposed in the light emitting region and comprising a light emitting layer disposed between a first electrode and the second electrode, a dummy area disposed in the non-light emitting region and comprising a dummy pad, an insulating film disposed over the substrate and covering half or more of the dummy pad, and common films disposed over the dummy pad or the insulating film. The dummy pad and the second electrode disposed corresponding to the dummy pad are spaced apart from each other.

A light emitting device according to another embodiment of the present invention may include a substrate comprising a light emitting region and a non-light emitting region, a scan driver disposed in the non-light emitting region and supplying a scan signal, a data driver disposed in the non-light emitting region and supplying a data signal and a bias signal, a scan line electrically connected to the scan driver and transferring the scan signal, a first data line electrically connected to the data driver and transferring the data signal, a second data line electrically connected to the data driver and transferring the bias signal, a sub-pixel disposed in the light emitting region and receiving the data signal and the scan signal from the first data line and the scan line, and a dummy area disposed in the non-light emitting region and receiving the bias signal and the scan signal from the second data line and the scan line.

A light emitting device according to another embodiment of the present invention may include a substrate comprising a light emitting region and a non-light emitting region, a second electrode disposed over the substrate, a sub-pixel disposed in the light emitting region and comprising a light emitting layer disposed between a first electrode and the second electrode, a contact pad disposed in the non-light emitting region and adjacent to outside the sub-pixel, and an insulating film disposed over the substrate and having a plurality of openings on the contact pad.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention.

FIGS. 1 to 3 are views illustrating a general light emitting device;

FIGS. 4 to 7 are views illustrating a light emitting device according to an embodiment of the present invention;

FIGS. 8 and 9 are views illustrating a light emitting device according to another embodiment of the present invention;

FIGS. 10 and 11 are views illustrating a light emitting device according to still another embodiment of the present invention.

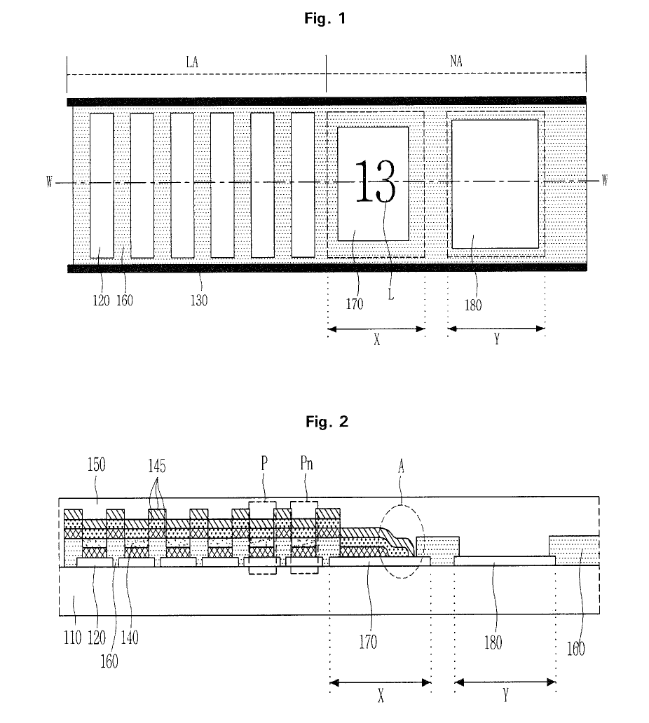

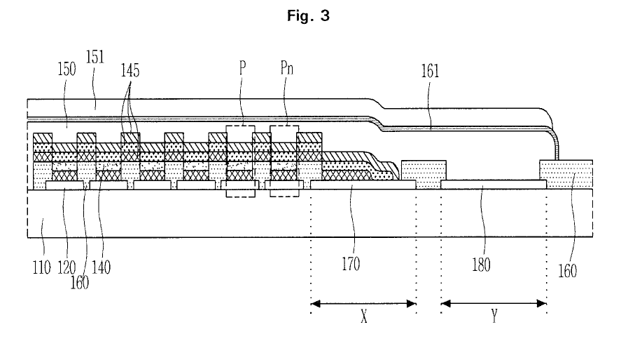

### DETAILED DESCRIPTION OF EMBODIMENTS

Hereinafter, implementations of this document will be described in detail with reference to the attached drawings.

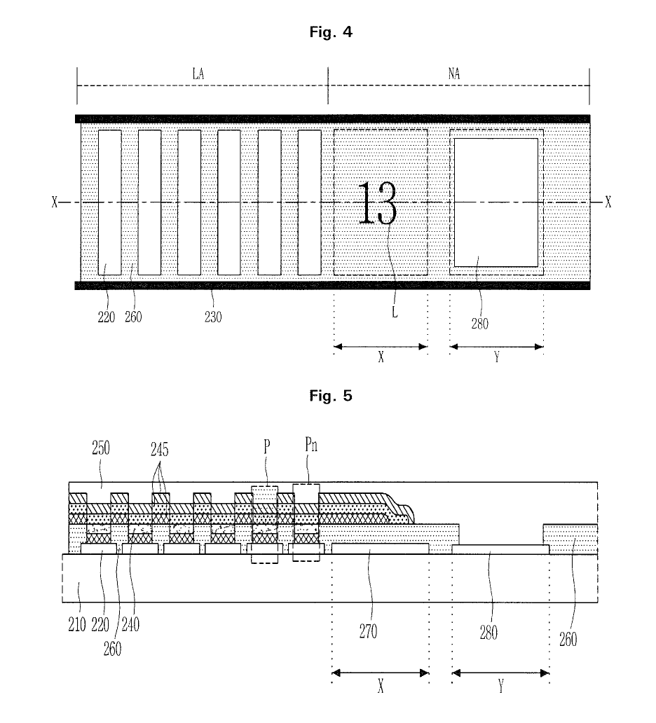

FIGS. 4 to 7 are views illustrating a light emitting device according to an embodiment of the present invention.

Referring to FIGS. 4 and 5, FIG. 4 is a partial plan view of the light emitting device according to an embodiment of the present invention, and FIG. 5 is a sectional view taken along line “X-X” of FIG. 4. For convenience of description, it is to be noted that light emitting layers 240, second electrodes 250, and common films 245 are not shown in FIG. 4.

The light emitting device according to an embodiment of the present invention may include a substrate 210, first electrodes 220, the second electrodes 250, the common films 245, the light emitting layers 240, a dummy pads 270, a contact pads 280, and an insulating film 260.

The substrate 210 may be made of transparent glass or plastic material.

The first electrode 220 is disposed over the substrate 210. It is to be noted that the first electrode 220 may serve as an anode electrode, but may serve as a cathode electrode in an inverted light emitting device. The first electrode 220 may be formed from ITO, IZO or the like, but not limited thereto. That is, the first electrode 220 may have a multi-layer structure including other metal electrode.

A thin film transistor having a source electrode, a drain electrode, a gate electrode, and a semiconductor layer may be disposed in the substrate 210 every sub-pixel. The first electrode 220 may be electrically connected to either the source electrode or the drain electrode. It is described that a light emitting device including the thin film transistor is an active driving type, but is well known in the art and does not belong to the technical spirit of the present invention. Thus, the active driving type is described in short.

A sub-pixel of the active matrix type includes one or more thin film transistors, a capacitor, and a light emitting layer. One or more thin film transistors include a switching thin film transistor for switching a scan signal and a driving thin film transistor that is operated in response to a data signal. The organic light emitting layer 240 is electrically connected to a source or drain electrode of the driving thin film transistor.

In general, this thin film transistor includes a semiconductor layer, a first insulating film (that is, a gate insulating film), a gate electrode, a second insulating film (that is, an interlayer dielectric film), a source electrode, and a drain electrode over a substrate, though not shown in the drawings.

In this active matrix type, if the switching thin film transistor is turned on in response to the scan signal and the data signal is supplied, the data signal is stored in a capacitor connected to the driving thin film transistor. The driving thin film transistor is driven in response to the data signal stored in the capacitor, so the light emitting layer emits light.

The insulating film 260 having opening formed on the first electrode 220 is formed on the substrate 210.

The light emitting layer 240 is disposed over the first electrode 220 exposed through the opening. The light emitting layer 240 is intervened between the common films 245, which are generally made of an organic material or an inorganic material. Each of common films 245 may include at least one of a hole injection layer (HIL), a hole transfer layer (HTL), an electron transfer layer (ETL) and an electron injection layer (EIL).

The light emitting layer 240 disposed between the common films 245 may include an organic material or an inorganic material. In the present invention, an organic light emitting device in which the light emitting layer 240 is formed from an organic material is described as an example. However, it will be evident that the present invention is not limited to the above example.

The second electrodes 250 to cross the first electrodes 220 are disposed over the light emitting layer 240. The second electrodes 250 may serve as a cathode electrode, but may serve as an anode electrode in an inverted light emitting device.

The second electrodes 250 are separated by barrier ribs 230 disposed on the insulating film 260 on a scan-line basis.

The first electrodes 220 and the second electrodes 250 may have different material, thickness, etc. depending on a top-emission structure or a bottom-emission emitting structure.

As described above, the first electrode 220, the light emitting layer 240, and the second electrode 250 disposed over the substrate 210 constitute one sub-pixel P. The sub-pixel P is disposed in a light emitting region LA defined on the substrate 210.

At least one dummy area X and at least one contact area Y are disposed external to a sub-pixel Pn that is located at the outermost, of the sub-pixels P disposed on the substrate 210. The term “external” refers to a direction directed from the center of the substrate 210 to the outside.

The dummy area X and the contact area Y may include the dummy pad 270 and the contact pad 280, respectively. The dummy area X and the contact area Y are located in a non-light emitting region NA not the light emitting region LA. The dummy area X is disposed between the sub-pixel Pn that is disposed at the outermost and the contact area Y on the non-light emitting region NA. The dummy area X is disposed external to the sub-pixel Pn that is disposed at the outermost. The contact area Y is disposed external to the dummy area X.

The contact pad 280 is electrically connected to the second electrode 250 through the opening of the insulating film 260 formed on the contact pad 280.

The dummy pad 270 may be formed from the same material as that of the first electrode 220, but not limited thereto. A character, number, symbol, etc. for identifying each line may be indicated in the dummy pad 270. A line number ‘L’ serves as an indicator to easily identify a line depending on its deposition location when the second electrode 250 is formed. In this case, it is to be noted that a number ‘13’ is used.

Further, the dummy area including the dummy pad may be used as a monitoring pixel.

The insulating film 260 according to an embodiment of the present invention may be formed to cover the entire top surface of the dummy pad 270.

In this structure, the common films 245 are disposed over the dummy area X (that is, on the insulating film 260). The light emitting layer 240 is not included between the common films 245 formed on the insulating film 260.

The dummy area X is described in more detail below. The common films 245 are formed on the insulating film 260 disposed on the dummy pad 270. The common films 245 are not formed constantly, but may be disposed having a step as shown. This may inevitably occur in almost the deposition processes including the common films 245.

Thus, if the insulating film 260 is formed to cover the entire top surface of the dummy pad 270 according to an embodiment of the present invention, it can prevent a defective spot problem due to the leakage current, which is generated as the dummy pad 270 becomes very close or connects to the second electrode 250 since the common films 245 are deposited irregularly over the dummy pad 270. Accordingly, the display quality of the light emitting device can be improved.

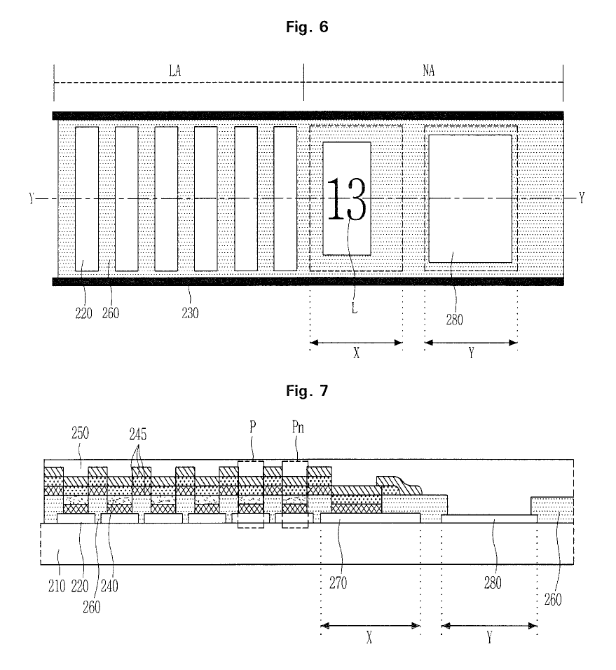

A general construction of a light emitting device shown in FIGS. 6 and 7 is the same as that of the light emitting device in FIGS. 4 and 5. Thus, description of the same technical spirit is omitted and only different technical characteristics are described below.

An insulating film 260 is formed to cover half or more a top surface of a dummy pad 270.

A dummy area X is described. The insulating film 260 disposed on the dummy pad 270 may cover half or more the top surface of the dummy pad 270. If the insulating film 260 covers half or more the top surface of the dummy pad 270, common films 245 that are deposited subsequently can cover the entire dummy pad 270 so that the dummy pad 270 is not exposed.

More specifically, the insulating film 260 has to cover the top surface of the dummy pad 270 to the extent that the dummy pad 270 is not exposed by the common films 245 that are deposited subsequently. In general, if the insulating film 260 covers half or more the top surface of the dummy pad 270, the common films 245 that are deposited subsequently can be deposited not to expose the dummy pad 270.

Therefore, in the above structure, a defective spot problem due to the leakage current, which is generated as the dummy pad 270 becomes very close or connects to a second electrode 250 since the common films 245 are deposited irregularly over the dummy pad 270, in particular, a problem in which luminance of a sub-pixel located at the outermost of a panel is reduced can be solved. Accordingly, the display quality of a light emitting device can be enhanced.

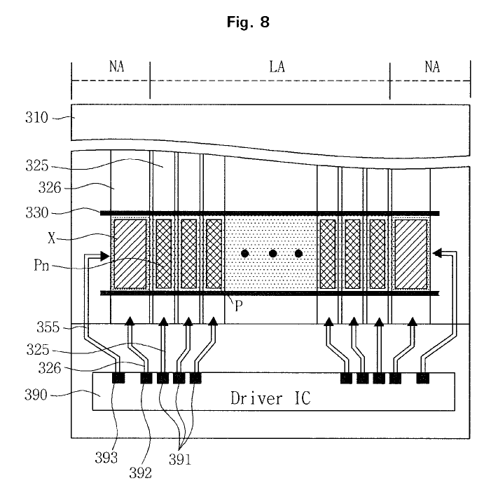

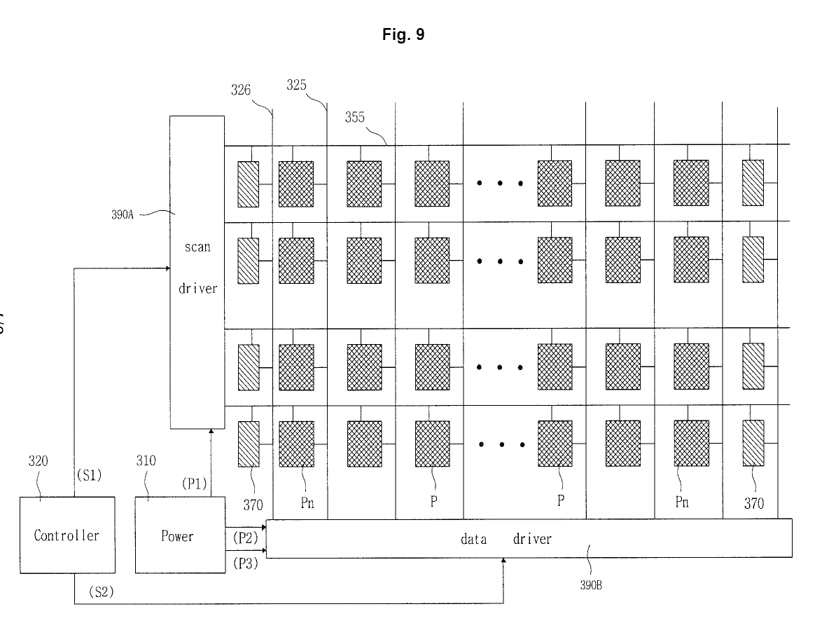

FIGS. 8 and 9 are views illustrating a light emitting device according to another embodiment of the present invention.

In the present embodiment, description of the same characteristics as those of the light emitting device according to an embodiment of the present invention is omitted, and only new technological characteristics are described below.

FIG. 8 is a schematic plan view of a light emitting device according to another embodiment of the present invention. Referring to FIG. 8, the light emitting device according to another embodiment of the present invention may include a scan driver 390A, a data driver 390B, scan lines 355, first data lines 325, and second data lines 326.

The constituent elements are first described in short. The scan driver 390A may supply a scan signal, and the data driver 390B may supply a data signal and a bias signal.

The scan lines 355 are electrically connected to the scan driver 390A and may supply the scan signal to a sub-pixel P and a dummy area X. The first data lines 326 are electrically connected to the data driver 390B and may supply the data signal to the sub-pixel. The second data lines 326 are also electrically connected to the data driver 390B and may supply the bias signal to the dummy area X.

More specifically, dummy pads disposed in a non-light emitting region NA on the substrate 310 are electrically connected to a driver 390. The driver 390 is divided into the data driver 390B for supplying the sub-pixel P with the data signal and the bias signal, and the scan driver 390A for supplying the scan signal. In the present invention, however, an example in which the driver 390 is included in one Integrated Circuit (IC) is described.

The dummy pads are connected to the second data lines 326 in order to receive the bias signal from the data driver 390B. The second data lines 326 are disposed externally to the first data lines 325.

Meanwhile, the driver 390 includes first pads 391 for supplying the data signal to the sub-pixel P, a second pad 392 for supplying the bias signal to the sub-pixel P, and a third pad 393 for supplying the scan signal to the sub-pixel P. The second pad 392 is disposed between the first pads 391 and the third pad 393. The first pads 391 are electrically connected to the first data lines 325. The second pad 392 is electrically connected to the second data lines 326. The third pad 393 is electrically connected to the scan lines 355.

The dummy area X may include a dummy pad, second electrodes, common films, and an insulating film. The dummy pad is electrically connected to the second data line 326 and may receive the bias signal, and the second electrode is electrically connected to the scan line 355 and may receive the scan signal.

The sub-pixel may include a first electrode, second electrodes, common films, and light emitting layers. The first electrode is electrically connected to the first data line 325 and may receive the data signal, and the second electrode is electrically connected to the scan line 355 and may receive the scan signal.

The light emitting display device shown in FIG. 8 has the same circuit configuration as that of FIG. 9.

Referring to FIG. 9, a controller 320 is electrically connected to the scan driver 390A and the data driver 390B, and supplies control signals S1 and S2, including the scan signal, the data signal or the bias signal, to the scan driver 390A and the data driver 390B, respectively.

A power generator 310 is electrically connected to the scan driver 390A and the data driver 390B, and supplies a power supply source P1 to the scan driver 390A and power supply sources P2 and P3 to the data driver 390B.

At this time, the power supply source P2 includes a specific current or voltage between a power supply source VCC and the ground, which corresponds to an output signal between the scan driver 390A and the data driver 390B. At this time, the specific current or voltage may correspond to the data signal or the bias signal.

The data driver 390B receives a specific current or voltage from the power generator 310 and supplies the bias signal to the dummy pad 370. At this time, the specific current or voltage corresponds to a specific current or voltage value that may be generated from the power generator 310.

As mentioned earlier in an embodiment of the present invention, the dummy pad 370 may become close or connect to the second electrode during a deposition process. Emission luminance of a sub-pixel located outside may be degraded due to the leakage current generated at this time. In order to flow a current as much as the leakage current or a higher current than the leakage current through the dummy pad 370, the data driver 390B may apply a specific current or voltage by applying the bias signal to the dummy pad 370.

Therefore, the bias signal or a specific current or voltage applied to the dummy pad 370 can be supplemented with a current as much as the leakage current or a higher current. A defective spot, in particular, a problem in which luminance of a sub-pixel located at the outermost is reduced can be solved. Accordingly, the display quality can be improved.

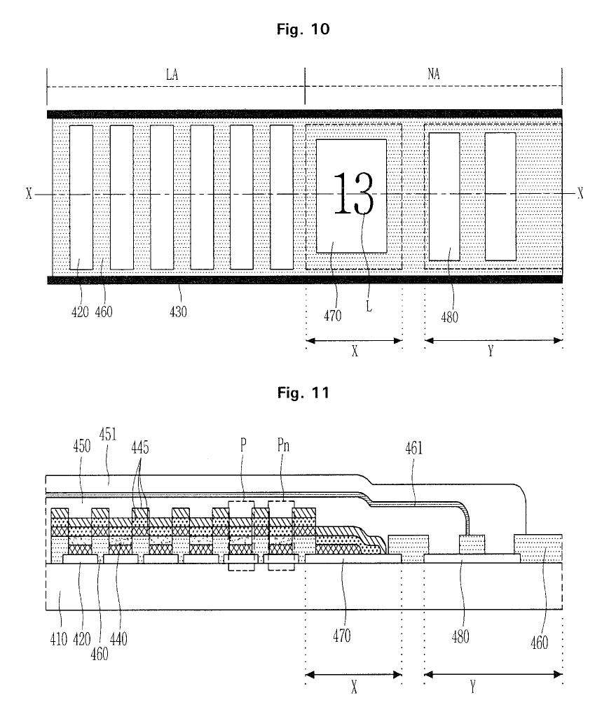

FIGS. 10 and 11 are views illustrating a light emitting device according to still another embodiment of the present invention.

In the present embodiment, description of the same characteristics as those of the light emitting device according to an embodiment of the present invention or another embodiment of the present invention is omitted, and only new technological characteristics are described below.

Referring to FIGS. 10 and 11, as described in the above embodiments, first electrodes 420, light emitting layers 440, and second electrodes 450 and 451 disposed over a substrate 410 respectively constitute sub-pixels P. The sub-pixel P is disposed in a light emitting region LA defined on the substrate.

Contact pad 480 is disposed external to a sub-pixel Pn that is disposed externally, of the sub-pixels P disposed on the substrate 410. At this time, the contact pad 480 is disposed in the non-light emitting region NA not the light emitting region LA. An insulating film 460 having a plurality of openings is disposed on the contact pad 480.

Meanwhile, a dummy area X including the dummy pad 470 may be disposed between the sub-pixel Pn that is disposed externally, of the sub-pixels P, and the contact pad 480. The insulating film 460 is disposed on the dummy pad 470. At this time, the insulating film 460 may be disposed on the dummy pad 470, having the opening.

Accordingly, the dummy area X is disposed further external to the sub-pixel Pn that is disposed externally. The contact pad 480 is disposed externally to the dummy area X. For reference, the contact pad 480 may have an area wider than that of the dummy pad 470.

The second electrodes 450 and 451 may be formed through twice or more depositions so that they have a multi-layer structure, as shown in the drawings. In this case, the second electrode 450 formed by the first deposition and the second electrode 451 formed by the second deposition are separately formed in the contact pads 480, respectively, through the plurality of openings.

In addition to the description, the second electrode 450 formed by the first deposition is brought in contact with the contact pad 480 through the opening disposed inside. The second electrode 451 formed by the second deposition is brought in contact with the contact pad 480 through the opening disposed outside.

Therefore, an area on which the second electrode 450 is contacted to contact pad 480 may be decided depending on the position, distance, and so on of the opening disposed over the contact pad 480.

In accordance with this structure, each of the plurality of second electrodes 450 and 451 is electrically connected to the contact pad 480 through each of different openings. Accordingly, even though an insulating layer by an oxide layer 461 is formed on the second electrode 450 after the second electrode 450 is deposited, an electrical characteristic may not be degraded.

Furthermore, there is an advantage in that although impurities, such as particles, are generated on the second electrode 450 formed by the first deposition in the deposition process, influence accordingly, such as increased resistance or signal distortion, can be minimized.

While this document has been described in connection with what is presently considered to be practical exemplary embodiments, it is to be understood that this document is not limited to the disclosed embodiments, but, on the contrary, is intended to cover various modifications and equivalent arrangements included within the spirit and scope of the appended claims.

What is claimed is:

1. A light emitting device, comprising:
a substrate comprising a light emitting region and a non-light emitting region;
a second electrode disposed over the substrate;
a sub-pixel disposed in the light emitting region and comprising a light emitting layer disposed between a first electrode and the second electrode;
a dummy area disposed in the non-light emitting region and comprising a dummy pad;
an insulating film disposed over the substrate and covering half or more of the dummy pad; and
common films disposed over the dummy pad or the insulating film,
wherein the dummy pad and the second electrode disposed corresponding to the dummy pad are spaced apart from each other.

2. The light emitting device of claim 1, wherein the insulating film is formed to cover the entire dummy pad.

3. The light emitting device of claim 1, wherein a contact area adjacent to outside the dummy area is disposed in the non-light emitting region, and the contact area includes the contact pad.

4. The light emitting device of claim 3, wherein:
the insulating film is disposed on the contact pad, and
the contact pad is electrically connected to the second electrode through opening formed in the insulating film.

5. The light emitting device of claim 1, wherein the light emitting layer is made of an organic material.

6. The light emitting device of claim 1, wherein a material constituting the dummy pad is the same as that constituting the first electrode.

7. The light emitting device of claim 1, wherein the substrate comprises a thin film transistor.

8. A light emitting device, comprising:
a substrate comprising a light emitting region and a non-light emitting region;
a scan driver disposed in the non-light emitting region and supplying a scan signal;
a data driver disposed in the non-light emitting region and supplying a data signal and a bias signal;
a scan line electrically connected to the scan driver and transferring the scan signal;
a first data line electrically connected to the data driver and transferring the data signal;
a second data line electrically connected to the data driver and transferring the bias signal;
a sub-pixel disposed in the light emitting region and receiving the data signal and the scan signal from the first data line and the scan line; and
a dummy area disposed in the non-light emitting region and receiving the bias signal and the scan signal from the second data line and the scan line.

9. The light emitting device of claim 8, wherein the bias signal is a specific current or voltage.

10. The light emitting device of claim 8, wherein:
the data driver comprises a first pad connecting the data driver and the first data line, and a second pad connecting the data driver and the second data line, and
the second pad is disposed adjacent to outside the first pad.

11. The light emitting device of claim 10, wherein a third pad is disposed adjacent to outside the second pad.

12. The light emitting device of claim 8, wherein the dummy area comprises:
a dummy pad electrically connected to the second data line;
a second electrode electrically connected to the scan line; and
common films disposed between the dummy pad and the second electrode and comprising at least one of an organic material and an inorganic material.

13. The light emitting device of claim 8, wherein the sub-pixel comprises:
a first electrode electrically connected to the first data line;
a second electrode electrically connected to the scan line;
common films disposed between the first electrode and the second electrode and comprising at least one of an organic material and an inorganic material; and
a light emitting layer intervened between the common films.

14. The light emitting device of claim 8, wherein the substrate comprises a thin film transistor.

15. A light emitting device, comprising:
a substrate comprising a light emitting region and a non-light emitting region;
a second electrode disposed over the substrate;
a sub-pixel disposed in the light emitting region and comprising a light emitting layer disposed between a first electrode and the second electrode;
a contact pad disposed in the non-light emitting region and adjacent to outside the sub-pixel; and
an insulating film disposed over the substrate and having a plurality of openings on the contact pad.

16. The light emitting device of claim 15, wherein the second electrode connects with the contact pad through the plurality of openings.

17. The light emitting device of claim 15, wherein:
the second electrode has multiple layers, and
each of the multiple layers connects with the contact pad through each of the plurality of openings.

18. The light emitting device of claim 15, further comprising a dummy area, which is disposed between a sub-pixel located at an outermost of the sub-pixels and the contact pad and includes a dummy pad.

19. The light emitting device of claim 15, wherein the light emitting layer is made of an organic material.

20. The light emitting device of claim 15, wherein the substrate comprises a thin film transistor.
